(19) United States
(12) Patent Application Publication
(10) Pub. No.: US 2026/0369531 A1
(43) Pub. Date: Nov. 19, 2026

(54) RING OF AN EDGE RING ASSEMBLY FOR AN ETCHING SYSTEM

(71) Applicant: TAIWAN SEMICONDUCTOR MANUFACTURING COMPANY, LTD., Hsinchu (TW)

(72) Inventors: Yi Chiuan Xu, New Taipei City (TW); Shun-Ping Wang, Hsinchu (TW); Che-Cheng Chang, New Taipei City (TW); Chen-Hsiang Lu, Hsinchu (TW)

(21) Appl. No.: 19/752,616

(22) Filed: Jul. 24, 2026

Related U.S. Application Data
(62) Division of application No. 18/221,701, filed on Jul. 13, 2023.

(51) Int. Cl. H01J 37/32; H10P 72/76

(52) U.S. Cl. CPC H01J 37/32642; H10P 72/7606; H01J 2237/3341

(57) ABSTRACT

A ring of an edge ring assembly for an etching system and methods of using the ring are described. In some embodiments, the ring includes a top portion including a side surface defining an opening sized to receive a center portion of a substrate support supporting a semiconductor wafer, and the top portion has a first constant thickness. The ring further includes a bottom portion integrally connected to the top portion, and the bottom portion has a second constant thickness that is about 15 percent to about 115 percent of the first constant thickness.

### CROSS-REFERENCE TO RELATED APPLICATIONS

This application is a divisional application of U.S. patent application Serial No. 18/221,701 filed Jul.13, 2023, which is incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography and etching processes to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise within each of the processes that are used, and these additional problems should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an etching system and an etching process in accordance with some embodiments.

FIGS. 2A and 2B illustrate a substrate support and an edge ring assembly disposed in the etching system, in accordance with some embodiments.

FIGS. 3A – 3D illustrates cross-sectional side views of a portion of a top ring of the edge ring assembly, in accordance with some embodiments.

FIG. 4 illustrates a side view of the top ring of the edge ring assembly, in accordance with some embodiments.

FIGS. 5A and 5B illustrate cross-sectional top views of the top ring taken along line A-A of FIG. 4, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A tool of manufacture for a semiconductor device is described in accordance with various embodiments. In particular, the tool of manufacture may be an etching system with an edge ring surrounding a wafer being processed. In some embodiments, the edge ring is configured to be lifted during the etching process. By lifting the edge ring, the uniformity of the openings formed by the etching process may be improved. The edge ring is configured so a gap is formed between the edge ring and another ring disposed below the edge ring, and an etchant can flow through the gap. As a result, no residue may be formed on the back surface of a top portion of the edge ring.

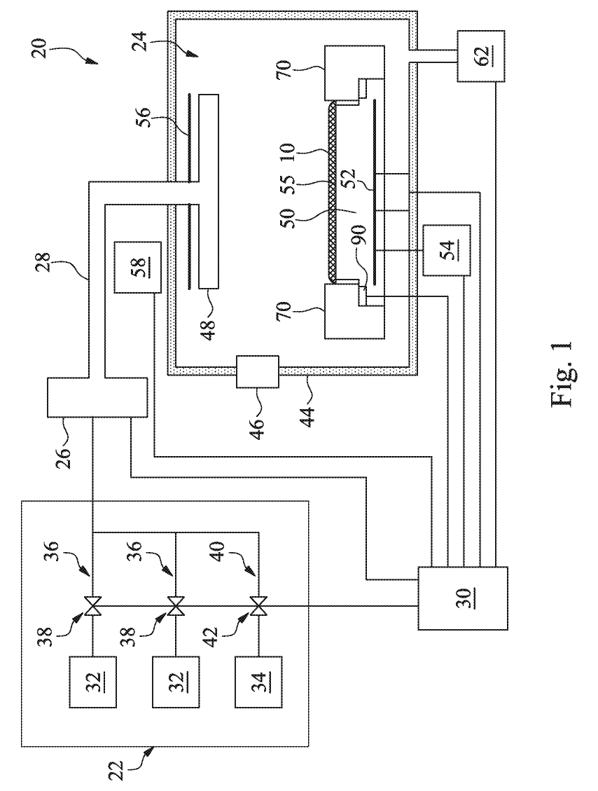

FIG. 1 shows an example process to etch a surface of the semiconductor wafer 10 by placing the semiconductor wafer 10 into an etching system 20. In some embodiments, the etching system 20 includes an etchant delivery system 22 that may deliver one or more gaseous etchants to an etching chamber 24. The etchant delivery system 22 supplies various etchants to the etching chamber 24 through an etchant controller 26 and a manifold 28. The etchant delivery system 22 may also help to control the flow rate of the etchant or etchants into the etching chamber 24 by controlling the flow and pressure of a carrier gas through the etchant delivery system 22. The etchant delivery system 22 and the etching chamber 24 are controlled by a controller 30, which controls and regulates the introduction of various etchants and carrier gases to the etching chamber 24. In some embodiments, the etching process performed by etching system 20 may be a reactive-ion etching (RIE) or deep reactive-ion etching (DRIE) process.

In some embodiments, the etchant delivery system 22 may include a plurality of etchant sources 32 along with a carrier gas source 34. Although only two of the etchant sources 32 are illustrated in FIG. 1, this is done merely for clarity, and it should be appreciated that any suitable number of etchant sources 32 may be included, such as one etchant source for each etchant desired to be used within the etching system 20. For example, in an embodiment in which five separate etchants will be utilized, there may be five etchant sources 32.

Each of the etchant sources 32 may be a vessel, such as a gas storage tank, that is located either locally to the etching chamber 24 or remotely from the etching chamber 24. In some embodiments, the etchant sources 32 may be part of a facility that independently prepares and delivers the predetermined etchants. Any suitable source for the predetermined etchants may be utilized as the etchant sources 32, and all such sources are fully intended to be included within the scope of the embodiments. Each of the etchant sources 32 supply an etchant to the etchant controller 26 through first lines 36 with first valves 38. The first valves 38 are controlled by the controller 30.

A carrier gas source 34 may supply a predetermined carrier gas, or diluent gas, that may be used to help push or “carry” the various predetermined etchants to the etching chamber 24. The carrier gas may be an inert gas or other gas that does not react with the etchant itself or with by-products from the etchant's reactions. For example, the carrier gas may be nitrogen gas (N₂), helium gas (He), argon gas (Ar), combinations thereof, or the like. Although other suitable carrier gases may be utilized.

The carrier gas source 34, or diluent source, may be a vessel, such as a gas storage tank, that is located either locally to the etching chamber 24 or remotely from the etching chamber 24. In some embodiments, the carrier gas source 34 may be a facility that independently prepares and delivers the carrier gas to the etchant controller 26. Any suitable source for the carrier gas may be utilized as the carrier gas source 34, and all such sources are fully intended to be included within the scope of the embodiments. The carrier gas source 34 may supply the predetermined carrier gas to the etchant controller 26 through a second line 40 with a second valve 42 that connects the carrier gas source 34 to the first lines 36. The second valve 42 is also controlled by the controller 30 that controls and regulates the introduction of the various etchants and carrier gases to the etching chamber 24. Once combined, the lines may be directed towards the etchant controller 26, for a controlled entry into the etching chamber 24 through the manifold 28.

In some cases, one or more of the etchant sources 32 may be separately connected to the etchant controller 26 through first lines 36 with first valves 38. The carrier gas source 34 may also be connected separately to the etchant controller 26 through the second line 40 with the second valve 42. In this manner, etchants from the etchant sources 32 and the carrier gas from the carrier gas source 34 may be supplied to the etchant controller 26 individually, in combination, or in sequence. Etchants and the carrier gas may be combined in the etchant controller 26 before being supplied to the manifold 28.

The etching chamber 24 may be any shape suitable for dispersing the etchant and contacting the etchant with the semiconductor wafer 10. In the embodiment illustrated in FIG. 1, the etching chamber 24 has a cylindrical sidewall and a bottom. However, the etching chamber 24 is not limited to a cylindrical shape, and any other suitable shape, such as a hollow square tube, an octagonal shape, or the like, may be utilized. Furthermore, the etching chamber 24 may be surrounded by an etchant chamber housing 44 made of material that is inert to the various process materials. As such, although the etchant chamber housing 44 may be any suitable material that can withstand the chemistries and pressures involved in the etching process, in an embodiment, the etchant chamber housing 44 may be steel, stainless steel, nickel, aluminum, alloys of these, combinations of these, and the like. In some embodiments, a slit valve 46 may be located in the sidewalls of the etchant chamber housing 44 for the semiconductor wafer 10 to be transferred in and out of the etching chamber 24. In some embodiments, the etching chamber 24 may be part of a cluster tool system (not shown). The cluster tool system may be used in conjunction with an automated handling system in order to position and place the semiconductor wafer 10 into the etching chamber 24 prior to the etching process, position and hold the semiconductor wafer 10 during the etching processes, and remove the semiconductor wafer 10 from the etching chamber 24 after the etching processes.

The etching chamber 24 includes a showerhead 48. In some embodiments, the showerhead 48 receives the various etchants from the manifold 28 and helps to disperse the various etchants into the etching chamber 24. The showerhead 48 may be designed to evenly disperse the etchants in order to minimize undesired process conditions that may arise from uneven dispersal. In some embodiments, the showerhead 48 may have a circular design with openings dispersed evenly around the showerhead 48 to allow for the dispersal of the etchants into the etching chamber 24. However, any suitable method of introducing the etchants, such as entry ports, may be utilized to introduce the etchants into the etching chamber 24.

A substrate support 50 is located within the etching chamber 24 in order to position and control the semiconductor wafer 10 during the etching process. In some cases, the semiconductor wafer 10 may be mounted onto a mounting surface 55 of the substrate support 50. In some embodiments, the substrate support 50 is an electrostatic chuck (ESC), and the substrate support 50 may hold the semiconductor wafer 10 using electrostatic forces. In some embodiments, the substrate support 50 holds the semiconductor wafer using clamps, vacuum pressure, combinations of these, or the like. The substrate support 50 may also include heating and cooling mechanisms in order to control the temperature of the semiconductor wafer 10 during the etching process.

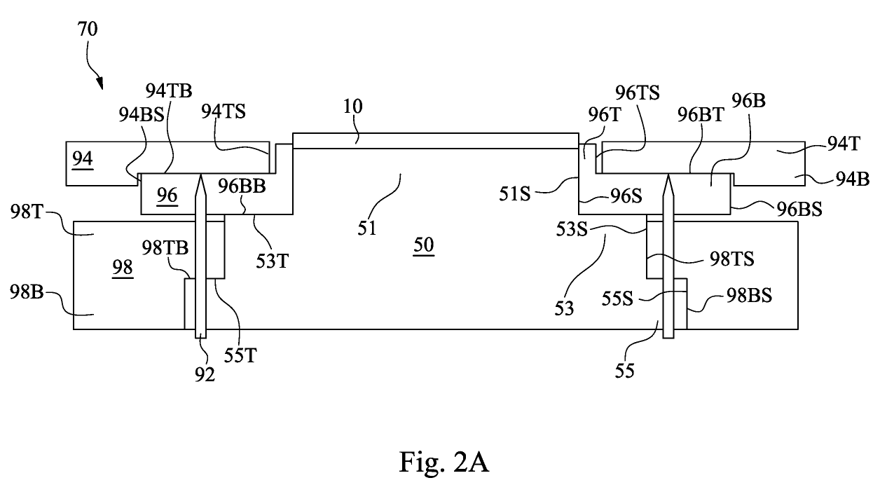

The substrate support 50 also includes an edge ring assembly 70 disposed thereon. The edge ring assembly 70 surrounds the semiconductor wafer 10 and at least a portion of the substrate support 50. The edge ring assembly 70 and the substrate support 50 are described in detail in FIGS. 2A and 2B. In some embodiments, actuators 90 are disposed in the substrate support 50 to actuate push pins 92 (FIGS. 2A and 2B), which in turn lifts or lowers a top ring 94 (FIGS. 2A and 2B) of the edge ring assembly 70. In some embodiments, the actuators 90 are disposed below the substrate support 50. The actuator 90 may be internal to or external to the chamber housing 44. The actuator 90 may include any suitable device, such as a stepper motor, another type of motor, or a hydraulic system. In some embodiments, the actuator 90 may move the push pins 92 directly, or may be connected to the edge ring assembly 70 by linkages, gearing, cables, hydraulics, or another suitable technique or combination of techniques. The actuator 90 is controlled by the controller 30.

In some embodiments, the etching chamber 24 includes a lower electrode 52 coupled to a lower RF generator 54. The lower electrode 52 may be electrically biased by the lower RF generator 54 (under control of the controller 30) at an RF voltage during the etching process. By being electrically biased, the lower electrode 52 is used to provide a bias to the incoming etchants and assist to ignite them into a plasma. The lower electrode 52 is also utilized to maintain the plasma during the etching process by maintaining the bias and also to help accelerate ions from the plasma towards the semiconductor wafer 10.

The etching chamber 24 also includes an upper electrode 56 coupled to an upper RF generator 58, for use as a plasma generator. In some embodiments, the plasma generator may be a transformer coupled plasma generator and may be, e.g., a coil. The upper RF generator 58 provides power to the upper electrode 56 (under control of the controller 30) in order to ignite the plasma during introduction of the etchants.

Although the upper electrode 56 is described above as a capacitively coupled plasma generator, embodiments are not intended to be limited to a capacitively coupled plasma generator. Rather, any suitable method of generating the plasma, such as inductively coupled plasma systems, magnetically enhanced reactive ion etching, electron cyclotron resonance, a remote plasma generator, or the like, may be utilized. All such methods are fully intended to be included within the scope of the embodiments.

The etching chamber 24 may also be connected to a vacuum pump 62. In some embodiments, the vacuum pump 62 is under the control of the controller 30, and may be utilized to control the pressure within the etching chamber 24 to a predetermined pressure. Additionally, once the etching process is completed, the vacuum pump 62 may be utilized to evacuate the etching chamber 24 in preparation for removal of the semiconductor wafer 10.

Although a number of particular parts of the etching system 20 have been described above, other suitable parts may also be included. For example, endpoint mounts, liners, and any other parts that may help operate or control the etching process may also be included. All such parts are fully intended to be included within the scope of the embodiments.

FIGS. 2A and 2B illustrate the substrate support 50 and the edge ring assembly 70 disposed in the etching system 20, in accordance with some embodiments. As shown in FIG. 2A, the substrate support 50 includes a center portion 51, a first outer portion 53 extending radially outward from the center portion 51, and a second outer portion 55 extending radially outward from the first outer portion 53. In some embodiments, the center portion 51 is circular, the first and second outer portions 53, 55 are annular, and the center portions and the first and second outer portions 53, 55 are concentric. In some embodiments, the edge ring assembly 70 includes the top ring 94 disposed over a middle ring 96, which is disposed over a bottom ring 98. Each of the top ring 94, the middle ring 96, and the bottom ring 98 may be fabricated from a conductive material, a semiconductor material, or an insulating material. In some embodiments, the top ring 94, the middle ring 96, and the bottom ring 98 are fabricated from a silicon-containing material, such as doped or undoped silicon, SiC, or other suitable silicon-containing material.

The bottom ring 98 may be disposed on the second outer portion 55 of the substrate support 50. In some embodiments, the bottom ring 98 includes a top portion 98T and a bottom portion 98B. The top portion 98T and the bottom portion 98B of the bottom ring 98 may be annular, and the inner diameter of the top portion 98T is substantially greater than the inner diameter of the bottom portion 98B. The top portion 98T and the bottom portion 98B of the bottom ring 98 may be monolithic. In some embodiments, the top portion 98T of the bottom ring 98 has a bottom surface 98TB in contact with a top surface 55T of the second outer portion 55 of the substrate support 50. A side surface 98TS of the top portion 98T of the bottom ring 98 may be spaced apart from a side surface 53S of the first outer portion 53 of the substrate support 50, and a side surface 98BS of the bottom portion 98B of the bottom ring 98 may be spaced apart from a side surface 55S of the second outer portion 55 of the substrate support 50. In some embodiments, the gap between the side surface 98BS and the side surface 55S is substantially smaller than the gap between the side surface 98TS and the side surface 53S. Because the substrate support 50 and the edge ring assembly 70 may be rotating during the etching process, the bottom portion 98B of the bottom ring 98 may be used to secure the bottom ring 98. Thus, the larger gap between the side surface 98TS and the side surface 53S ensures that the side surfaces 98TS and 53S do not come into contact during operation, which in turn reduces the risk of creating contaminants.

As shown in FIG. 2A, the middle ring 96 includes a top portion 96T and a bottom portion 96B. The top portion 96T and the bottom portion 96B of the middle ring 96 may be annular, and the outer diameter of the top portion 96T is substantially less than the outer diameter of the bottom portion 96B. The top portion 96T and the bottom portion 96B of the middle ring 96 may be monolithic. In some embodiments, the bottom portion 96B of the middle ring 96 has a bottom surface 96BB in contact with a top surface 53T of the first outer portion 53 of the substrate support 50. An inner side surface 96S of the middle ring 96 may be spaced apart from a side surface 51S of the center portion 51 of the substrate support 50.

As shown in FIG. 2A, the push pins 92 extends through the second outer portion 55 of the substrate support 50, the top portion 98T of the bottom ring 98, and the bottom portion 96B of the middle ring 96. Openings are formed in the second outer portion 55 of the substrate support 50, the top portion 98T of the bottom ring 98, and the bottom portion 96B of the middle ring 96 to accommodate the push pins 92. In some embodiments, a clearance of each push pin 92 in the corresponding opening formed in the middle ring 96 may be substantially smaller than the gap between the inner side surface 96S of the middle ring 96 and the side surface 51S of the center portion 51 of the substrate support 50. In other words, a distance between the push pin 92 and the sidewall of the opening is substantially less than the gap between the inner side surface 96S of the middle ring 96 and the side surface 51S of the center portion 51 of the substrate support 50. As a result, the movement of the middle ring 96 during the etching process is limited by the push pins 92, and the side surface 51S and the inner side surface 96S do not come into contact. As a result, the risk of creating contaminant is reduced.

Similarly, in some embodiments, a clearance of each push pin 92 in the corresponding opening formed in the bottom ring 98 may be substantially smaller than the gap between the side surface 98BS and the side surface 55S, and the movement of the bottom ring 98 during the etching process is limited by the push pins 92, and the side surfaces 55S and 98BS do not come into contact. As a result, the risk of creating contaminant is reduced.

As shown in FIG. 2A, the top ring 94 of the edge ring assembly 70 is disposed over the middle ring 96. The top ring 94 may include a top portion 94T and a bottom portion 94B. In some embodiments, the top portion 94T and the bottom portion 94B of the top ring 94 may be annular, and the inner diameter of the top portion 94T is substantially less than the inner diameter of the bottom portion 94B. The top portion 94T and the bottom portion 94B of the top ring 94 may be monolithic. In some embodiments, the top portion 94T of the top ring 94 has a bottom surface 94TB in contact with a top surface 96BT of the bottom portion 96B of the middle ring 96. A side surface 94TS of the top portion 94T of the top ring 94 may be spaced apart from an outer side surface 96TS of the top portion 96T of the middle ring 96, and a side surface 94BS of the bottom portion 94B of the top ring 94 may be spaced apart from an outer side surface 96BS of the bottom portion 96B of the middle ring 96. In some embodiments, the gap between the side surface 94BS and the outer side surface 96BS is substantially smaller than the gap between the side surface 94TS and the outer side surface 96TS. In some embodiments, during the etching process, the top ring 94 is disposed on and in contact with the middle ring 96. Because the substrate support 50 and the edge ring assembly 70 may be rotating during the etching process, the bottom portion 94B of the top ring 94 may be used to secure the top ring 94. Thus, the larger gap between the side surface 94TS and the outer side surface 96TS ensures that the side surface 94TS and the outer side surface 96TS do not come into contact during operation, which in turn reduces the risk of creating contaminants. In some embodiments, the opening defined by the side surface 94TS is sized to receive the center portion 51 of the substrate support 50 and the top portion 96T of the middle ring 96.

In some embodiments, the top ring 94 is lifted by the push pins 92 during etching process, as shown in FIG. 2B . In some embodiments, recesses (not shown) may be formed in the bottom surface 94TB of the top portion 94T of the top ring 94 to accommodate corresponding push pins 92. As a result, the top ring 94 is secured during the rotation of the substrate support 50 and the edge ring assembly 70 during operation. The raised top ring 94 may help with etching uniformity. In some embodiments, a gap G may be formed between the top ring 94 and the middle ring 96. The gap G may be defined as the shortest distance between the bottom portion 94B of the top ring 94 and the bottom portion 96B of the middle ring 96. The gap G allows the etchant(s) 102 to flow through the space between the top ring 94 and the middle ring 96. As a result, there is no material deposited on the bottom surface 94TB. The gap G may be greater than about 2 mm, such as from about 2 mm to about 5 mm. In some embodiments, the top ring 94 is lifted to a predetermined level to improve etching uniformity, and the predetermined level is about 6 mm from the top surface 96BT of the bottom portion 96B of the middle ring 96. In other words, when the top ring 94 is lifted, a predetermined distance D is between the bottom surface 94TB of the top portion 94T of the top ring 94 and the top surface 96BT of the bottom portion 96B of the middle ring 96. The distance D may be determined to improve etching uniformity and may not be used to adjust the gap G. Thus, the gap G ranging from about 2 mm to about 5 mm may be achieved by the top ring 94.

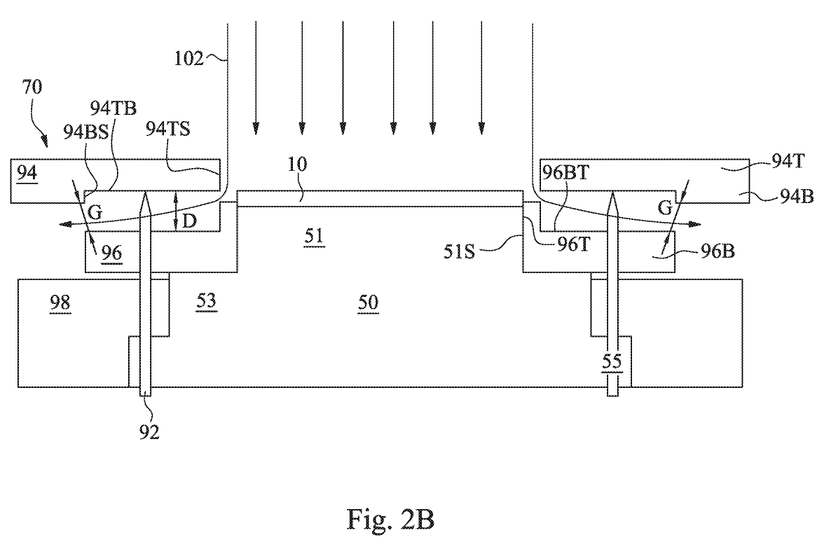

FIGS. 3A – 3D illustrates cross-sectional side views of a portion of the top ring 94 of the edge ring assembly 70, in accordance with some embodiments. As shown in FIG. 3A, in some embodiments, the top portion 94T of the top ring 94 has a thickness T1, and the bottom portion 94B of the top ring 94 has a thickness T2. The dotted line shown in FIG. 3A is an imaginary line separating the top portion 94T and the bottom portion 94B. The bottom portion 94B has a width W1. In some embodiments, the width W1 is determined so the gap between the side surface 94BS (FIG. 2A) and the outer side surface 96BS (FIG. 2A) is substantially smaller than the gap between the side surface 94TS (FIG. 2A) and the outer side surface 96TS (FIG. 2A). The thickness T1 of the top portion 94T may be constant, the thickness T2 of the bottom portion 94B may be constant, and the width W1 of the bottom portion 94B may be constant. In other words, the top portion 94T and the bottom portion 94B each may have a substantially rectangular cross-section, as shown in FIG. 3A. The thickness T2 may be 15 percent to about 115 percent of the thickness T1. For example, the thickness T1 may be about 3.46 mm, and the thickness T2 is less than about 4 mm, such as from about 0.52 mm to about 3.98 mm. If the thickness T2 is less than about 15 percent of the thickness T1, the bottom portion 94B may not be able to secure the top ring 94 on the middle ring 96 while the edge ring assembly 70 and the substrate support 50 are rotating during operation in the embodiment where the top ring 94 is not lifted. On the other hand, if the thickness T2 is greater than about 115 percent of the thickness T1, the gap G (FIG. 2B) may be too small to allow sufficient etchant(s) to pass through. As a result, materials, such as polymers (if the etchant is a carbon-containing etchant), may be deposited on the bottom surface 94TB.

As shown in FIG. 3B, in some embodiments, the bottom portion 94B has a thickness T4 which is substantially greater than the thickness T2 (FIG. 3A). For example, the thickness T4 is greater than about 150 percent of the thickness T1, such as from about 150 percent to about 250 percent of the thickness T1. The top ring 94 has an outer side surface 94S having a thickness T3, which is the sum of the thickness T1 and T4. The bottom portion 94B has a width W2 that is substantially smaller than the width W1 (FIG. 3A). In some embodiments, the width W2 is about 15 percent to about 30 percent of the thickness T3. For example, the thickness T3 may be about 12 mm, and the width W2 is less than about 3.6 mm, such as from about 1.8 mm to about 2.5 mm. If the width W2 is greater than about 30 percent of the thickness T3, the gap G (FIG. 2B) may be too small to allow sufficient etchant(s) to pass through. On the other hand, if the width W1 is less than about 15 percent of the thickness T3, the manufacturing cost is increased without significant advantage.

As shown in FIG. 3C, in some embodiments, the thickness and the width of the bottom portion 94B are not constant. For example, the bottom portion 94B may have a triangular cross-sectional shape. In some embodiments, the bottom portion 94B has a slanted surface 94SS extending from the bottom surface 94TB to the outer side surface 94S. The slanted surface 94SS and the bottom surface 94TB form an angle A. In some embodiments, the angle A is an obtuse angle. For example, the angle A may range from about 125 degrees to about 155 degrees. If the angle A is greater than about 155 degrees, the slanted surface 94SS may not be able to secure the top ring 94 on the middle ring 96 while the edge ring assembly 70 and the substrate support 50 are rotating during operation in the embodiment where the top ring 94 is not lifted. On the other hand, if the angle A is less than about 125 degrees, the gap G (FIG. 2B) may be too small to allow sufficient etchant(s) to pass through.

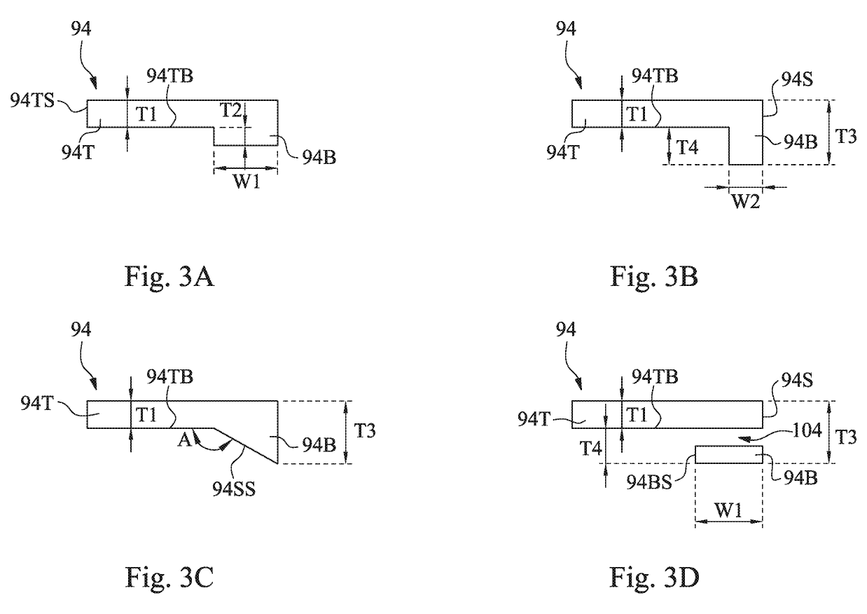

As shown in FIG. 3D, in some embodiments, the bottom portion 94B has the width W1, the thickness T4, and one or more openings 104 formed through the bottom portion 94B. FIG. 4 illustrates a side view of the top ring 94 of the edge ring assembly 70, in accordance with some embodiments. As shown in FIGS. 3D and 4, in some embodiments, a plurality of openings 104 are formed in the bottom portion 94B of the top ring 94. The openings 104 may have any suitable shape. In some embodiments, each opening 104 has a square or rectangular shape, as shown in FIG. 4. In some embodiments, each opening 104 has a circular or oval shape. The openings 104 extend from the outer side surface 94S to the side surface 94BS, as shown in FIG. 3D. The number of openings 104 and the distance between adjacent openings 104 may be determined so the total area of the plurality of openings 104 is about 30 percent to about 95 percent of the surface area of the outer side surface 94S. In other words, the bottom portion 94B of the top ring 94 may be perforated with about 30 percent to about 95 percent open area. If the total area of the plurality of openings 104 is less than about 30 percent of the area of the outer side surface 94S, the gap G (FIG. 2B) may be too small to allow sufficient etchant(s) to pass through. On the other hand, if the total area of the plurality of openings 104 is greater than about 95 percent of the area of the outer side surface 94S, the structural support of the top ring 94 may be compromised.

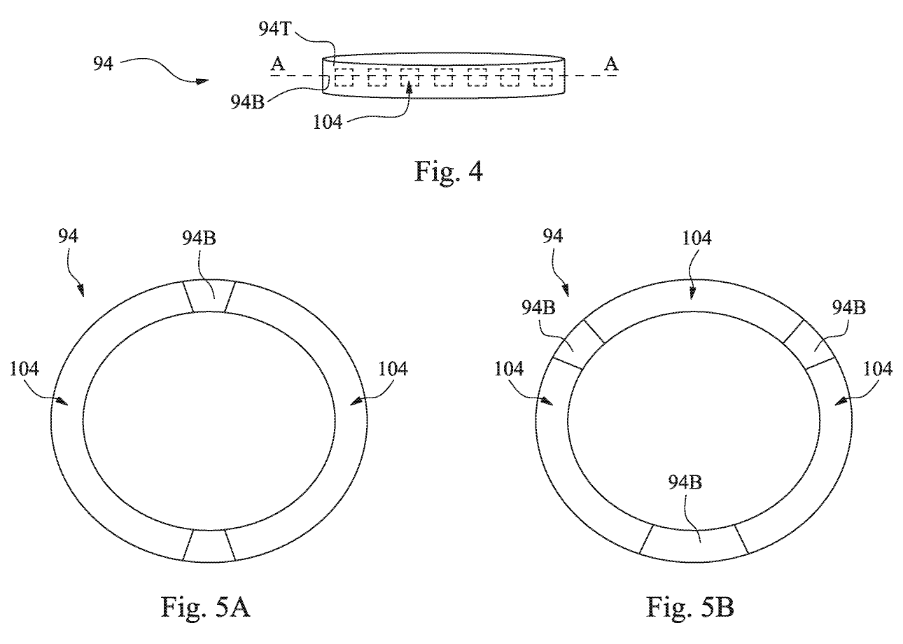

FIGS. 5A and 5B illustrate cross-sectional top views of the top ring 94 taken along line A-A of FIG. 4, in accordance with some embodiments. As shown in FIG. 5A, the bottom portion 94B of the top ring 94 includes two openings 104. Each opening 104 may be continuously extending along an arc of a circumference of the top ring 94. In some embodiments, the arc may be less than half of the circumference, but greater than one third of the circumference. In some embodiments, there are three openings 104 formed in the bottom portion 94B of the top ring 94, as shown in FIG. 5B. Each opening may be continuously extending along an arc of a circumference of the top ring 94. In some embodiments, the arc may be less than one third of the circumference, but greater than one fourth of the circumference.

Embodiments of the present disclosure provides an edge ring assembly 70 having a top ring 94. The top ring 94 includes a bottom portion 94B configured to form a gap G between the top ring 94 and the middle ring 96 during operation. Some embodiments may achieve advantages. For example, the gap G allows the etchant(s) to flow through a space between the top ring 94 and the middle ring 96. As a result, no material is deposited on the bottom surface 94TB of the top ring 94.

An embodiment is a ring of an edge ring assembly for an etching system. The ring includes a top portion including a side surface defining an opening sized to receive a center portion of a substrate support supporting a semiconductor wafer, and the top portion has a first constant thickness. The ring further includes a bottom portion integrally connected to the top portion, and the bottom portion has a second constant thickness that is about 15 percent to about 115 percent of the first constant thickness.

Another embodiment is an edge ring assembly. The edge ring assembly includes a bottom ring including a top portion and a bottom portion, and the top portion is configured to be in contact with a first outer portion of a substrate support of an etching system. The edge ring assembly further includes a middle ring disposed over the bottom ring, the middle ring includes a top portion and a bottom portion, and the bottom portion is configured to be in contact with a second outer portion of the substrate support of the etching system. The edge ring assembly further includes a top ring disposed over the middle ring by a distance, the top ring includes a top portion and a bottom portion, a gap is defined by a shortest distance between the bottom portion of the top ring and the bottom portion of the middle ring, and the gap ranges from about 2 mm to about 5 mm.

A further embodiment is a method. The method includes placing a semiconductor wafer on a substrate support in an etching system, and the substrate support is surrounded by an edge ring assembly. The method further includes lifting a top ring of the edge ring assembly, a gap is formed between a bottom portion of the top ring and a bottom portion of a middle ring of the edge ring assembly, and the gap ranges from about 2 mm to about 5 mm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A ring of an edge ring assembly for an etching system, comprising:
a top portion including a side surface defining an opening sized to receive a center portion of a substrate support supporting a semiconductor wafer, wherein the top portion has a first constant thickness; and
a bottom portion integrally connected to the top portion, wherein the bottom portion has a second constant thickness that is about 15 percent to about 115 percent of the first constant thickness.

2. The ring of claim 1, wherein the second constant thickness ranges from about 0.52 mm to about 3.98 mm.

3. The ring of claim 1, wherein the top portion has a rectangular cross section, and the bottom portion has a rectangular cross section.

4. The ring of claim 1, wherein the ring is fabricated from a conductive material, a semiconductor material, or an insulating material.

5. The ring of claim 4, wherein the ring is fabricated from a silicon-containing material.

6. An edge ring assembly, comprising:
a bottom ring comprising a top portion and a bottom portion, wherein the top portion is configured to be in contact with a first outer portion of a substrate support of an etching system;
a middle ring disposed over the bottom ring, where the middle ring comprises a top portion and a bottom portion, and the bottom portion is configured to be in contact with a second outer portion of the substrate support of the etching system; and
a top ring disposed over the middle ring by a distance, wherein the top ring comprises a top portion and a bottom portion, a gap is defined by a shortest distance between the bottom portion of the top ring and the bottom portion of the middle ring, and the gap ranges from about 2 mm to about 5 mm.

7. The edge ring assembly of claim 6, wherein the distance is substantially greater than the gap.

8. The edge ring assembly of claim 6, wherein the top portion of the top ring has a first thickness, and the bottom portion of the top ring has a second thickness that is about 15 percent to about 115 percent of the first thickness.

9. The edge ring assembly of claim 6, wherein the top ring further comprises an outer side surface having a third thickness.

10. The edge ring assembly of claim 9, wherein the bottom portion of the top ring has a width that is about 15 percent to about 30 percent of the third thickness.

11. The edge ring assembly of claim 10, wherein the third thickness is a sum of a thickness of the top portion of the top ring and a thickness of the bottom portion of the top ring.

12. The edge ring assembly of claim 11, wherein the thickness of the bottom portion of the top ring is about 150 percent to about 250 percent of the thickness of the top portion of the top ring.

13. The edge ring assembly of claim 6, wherein the bottom portion of the top ring has a triangular cross-section.

14. The edge ring assembly of claim 13, wherein the bottom portion of the top ring comprises a slanted surface, the slanted surface and a bottom surface of the top portion of the top ring form an angle, and the angle is an obtuse angle.

15. The edge ring assembly of claim 14, wherein the angle ranges from about 125 degrees to about 155 degrees.

16. The edge ring assembly of claim 6, wherein the bottom portion of the top ring is perforated.

17. A ring of an edge ring assembly for an etching system, comprising:
a top portion including a side surface defining an opening sized to receive a center portion of a substrate support supporting a semiconductor wafer, wherein the top portion has a first constant thickness; and
a bottom portion integrally connected to the top portion, wherein the bottom portion has a second constant thickness that is about 150 percent to about 250 percent of the first constant thickness.

18. The ring of claim 17, wherein a width of the bottom portion has a width that is about 15 percent to about 30 percent of a thickness of an outer side surface of the ring.

19. The ring of claim 18, wherein the width ranges from about 1.8 mm to about 2.5 mm.

20. The ring of claim 19, wherein the thickness of the outer side surface of the ring is about 12 mm.
